(19) United States
(12) Patent Application Publication
(10) Pub. No.: US 2024/0321802 A1
(43) Pub. Date: Sep. 26, 2024

(54) PROCESSOR PACKAGE SUBSTRATE WITH HIGH-SPEED TOP-SURFACE CONNECTION TO CABLE INTERCONNECT

(71) Applicant: INTERNATIONAL BUSINESS MACHINES CORPORATION, ARMONK, NY (US)

(72) Inventors: JUNYAN TANG, AUSTIN, TX (US); SUNGJUN CHUN, AUSTIN, TX (US); DANIEL MARK DREPS, GEORGETOWN, TX (US); WIREN DALE BECKER, HYDE PARK, NY (US); JOSE A HEJASE, PFLUGERVILLE, TX (US); PAVEL ROY PALADHI, PFLUGERVILLE, TX (US); NAM HUU PHAM, ROUND ROCK, TX (US)

(21) Appl. No.: 18/187,180

(22) Filed: Mar. 21, 2023

(51) Int. Cl. H01L 23/00; H01L 23/48; H01L 23/498; H01L 23/50

(52) U.S. Cl. CPC H01L 24/20; H01L 23/481; H01L 23/49827; H01L 23/50; H01L 24/45; H01L 24/85; H01L 2924/1432

(57) ABSTRACT

An integrated circuit and a cable interconnect interface are disposed on a substrate and in communication with one another. The cable interconnect interface includes a first plurality of connector pads arranged in a first column and a second plurality of connector pads arranged in a second column. A radio frequency absorption layer is disposed on one or more of the first plurality of connector pads and the second plurality of connector pads. The first plurality of connector pads includes a first group of transmission connector pads and a first group of receiving connector pads. The second plurality of connector pads includes a second group of transmission connector pads and a second group of receiving connector pads. The first group of transmission connector pads is opposite the second group of transmission connector pads, and the first group of receiving connector pads is opposite the second group of receiving connector pads.

### BACKGROUND

### Field of the Invention

The field of the invention generally relates to integrated circuit manufacturing, or, more specifically, apparatus and methods for high-speed connection of package substrates to cable interconnects.

### Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

Computer systems including multiple processors located on separate dies often use interconnect cables to transmit signals between the processors. An example of an interconnect cables that are used is to connect different integrated circuits together is that of twinaxial (“Twinax”) cabling. Twinax cabling includes two inner conductors in which differential signals are sent over the two conductors. Typically, each integrated circuit package includes a connector on a top surface of the substrate to facilitate coupling of the integrated circuits with cable interconnects. However, a challenge presented by existing techniques to interconnect integrated circuits is the difficulty in achieving high-speed transmission while minimizing crosstalk and coupling noise. Accordingly, methods and apparatus for improved high-speed connections between processor package substrates are desired.

### SUMMARY

An embodiment of a semiconductor package for high-speed connection to a cable interconnect includes an integrated circuit disposed on a substrate, and a cable interconnect interface disposed on the substrate and in communication with the integrated circuit. The cable interconnect interface includes a first plurality of connector pads arranged in a first column of the cable interconnect interface and a second plurality of connector pads arranged in a second column of the cable interconnect interface. A radio frequency absorption layer is disposed on one or more of the first plurality of connector pads and the second plurality of connector pads. The first plurality of connector pads includes a first group of transmission connector pads and a first group of receiving connector pads, and the second plurality of connector pads includes a second group of transmission connector pads and a second group of receiving connector pads. The first group of transmission connector pads is opposite the second group of transmission connector pads, and the first group of receiving connector pads is opposite the second group of receiving connector pads.

In some embodiments, the first plurality of connector pads are configured as differential pairs. In some embodiments, the cable interconnect interface further includes one or more ground pads adjacent to one or more of the differential pairs. In some embodiments, a surface area of the one or more ground pads is larger than a surface area of one of the first plurality of connector pads.

In some embodiments, the substrate comprises a first layer including a signal trace coupled to a first connector pad of the plurality of connector pads, wherein the signal trace being coupled to the first connector pad at an outer portion of the first connector pad. In some embodiments, the substrate further includes a ground pattern spaced around one or more sides of the first connector pad. In some embodiments, the signal traces passes through a portion of the ground pattern.

In some embodiments, the substrate further comprises a second layer, wherein the second layer includes a void formed therein. In some embodiments, the void is located under at least a portion of the first connector pad.

In some embodiments, the first column is positioned along a first side of the cable interconnect interface, and the second column is positioned along a second side of the cable interconnect interface. In some embodiments, the first side is positioned opposite of the first side.

In some embodiments, the semiconductor package further comprises a cable connector having a foot portion coupled to the one or more of the first plurality of connector pads and the second plurality of connector pads, wherein the foot portion is disposed within the radio frequency absorption layer.

An embodiment of a system for high-speed connection to a cable interconnect includes a first semiconductor package comprising a first cable interconnect interface disposed on a first substrate, the first cable interconnect interface including a first group of transmission connector pads and a first group of receiving connector pads arranged in a first column of the first cable interconnect interface, and a second group of transmission connector pads and a second group of receiving connector pads arranged in a second column of the first cable interconnect interface. The first group of transmission connector pads is opposite the second group of transmission connector pads, and the first group of receiving connector pads is opposite the second group of receiving connector pads.

In some embodiments, the system further includes a second semiconductor package comprising a second cable interconnect interface disposed on a second substrate, the second cable interconnect interface including a third group of transmission connector pads and a third group of receiving connector pads arranged in a first column of the second cable interconnect interface, and a fourth group of transmission connector pads and a fourth group of receiving connector pads arranged in a second column of the second cable interconnect interface. The third group of transmission connector pads, the third group of receiving connector pads, the fourth group of receiving connector pads, and the fourth group of receiving connector pads are arranged on the second cable interconnect interface in a pattern that is rotated one hundred and eighty degrees with respect to the arrangement of the first group of transmission connector pads, the first group of receiving connector pads, the second group of transmission connector pads, and the second group of receiving connector pads.

In some embodiments, the system further includes a first integrated circuit disposed on the first substrate and in communication with the first cable interconnect interface, and a second integrated circuit disposed on the second substrate and in communication with the second cable interconnect interface.

In some embodiments, the system further includes a cable configured to couple the first cable interconnect interface to the second cable interconnect interface. In some embodiments, the cable is configured to couple one of the first group of transmission connector pads of the first cable interconnect interface to one of the third group of receiving connector pads of the second cable interconnect interface. In some embodiments, the cable is configured to couple one of the third group of transmission connector pads of the second cable interconnect interface to one of the first group of receiving connector pads of the first cable interconnect interface.

In some embodiments, the system further includes a radio frequency absorption layer disposed on one or more of the transmission connector pads or the receiving connector pads.

An embodiment of a method for high-speed connection to a cable interconnect includes providing a first cable interconnect interface disposed on a first substrate, the first cable interconnect interface including a first group of transmission connector pads and a first group of receiving connector pads arranged in a first column of the first cable interconnect interface, and a second group of transmission connector pads and a second group of receiving connector pads arranged in a second column of the first cable interconnect interface. A radio frequency absorption layer is applied on one or more of the transmission connector pads and the receiving connector pads. The first group of transmission connector pads is opposite the second group of transmission connector pads, and the first group of receiving connector pads is opposite the second group of receiving connector pads.

In some embodiments, the method further includes providing a second cable interconnect interface disposed on a second substrate, the second cable interconnect connector including a third group of transmission connector pads and a third group of receiving connector pads arranged in a first column of the second cable interconnect interface, and a fourth group of transmission connector pads and a fourth group of receiving connector pads arranged in a second column of the second cable interconnect interface. The third group of transmission connector pads, the third group of receiving connector pads, the fourth group of receiving connector pads, and the fourth group of receiving connector pads are arranged on the second cable interconnect interface in a pattern that is rotated one hundred and eighty degrees with respect to the arrangement of the first group of transmission connector pads, the first group of receiving connector pads, the second group of transmission connector pads, and the second group of receiving connector pads. In some embodiments, the method further includes coupling the first cable interconnect interface to the second cable interconnect interface.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 illustrates a system for interconnection of package substrates in accordance with an embodiment.

FIGS. 2A-2B illustrate a high-speed connector interface for a processor package in accordance with an embodiment.

FIG. 3 illustrates a cable connector of a cable interconnect interface in accordance with an embodiment.

FIGS. 4A-4B illustrate an example TX/RX connector pad placement pattern and signaling designation for the cable connector of FIG. 3 in accordance with an embodiment.

FIG. 5A illustrates an example configuration of cable interconnect interfaces for interconnection of two package substrates in accordance with an embodiment.

FIG. 5B illustrates another example configuration of cable interconnect interfaces for interconnection of two package substrates.

FIG. 6 illustrates an example cable configuration for interconnection of package substrates in accordance with an embodiment.

FIG. 7 illustrates a package substrate layer including ground referencing and signal routing at a cable interconnect interface in accordance with an embodiment.

FIGS. 8A-8B illustrate an example signal routing in a package at a cable interconnect interface for impedance control to reduce stub effect in accordance with an embodiment.

FIGS. 9A-9C illustrate a multilayer package substrate in which one or more layers are voided under the connector pads in accordance with an embodiment.

FIG. 10 illustrates a profile view of a connector pad configuration in accordance with an embodiment.

FIG. 11 illustrates a top view of a top layer of a connector pad configuration in accordance with an embodiment.

FIG. 12 illustrates another example signal routing in a package at a cable interconnect interface to reduce stub effect in accordance with an embodiment.

FIG. 13 sets forth a flow chart illustrating an exemplary method for high-speed connection to a cable interconnect.

### DETAILED DESCRIPTION

Embodiments in accordance with the present disclosure provide for an apparatus and methods for high-speed connection of package substrates to cable interconnects. Exemplary embodiments provide for a cable interconnect interface between a processor package and a connector having a signal and ground connector pad arrangement configured to provide improved signal transmission characteristics. In particular embodiments, transmission connector pads, receiving connector pads, and ground connector pads are distributed within the cable interconnect interface in a pattern to provide improved isolation of crosstalk and coupling noise. In particular embodiments, the connector pads of two different coupled processor packages are arranged in such a way that the connectors are rotated by 180 degrees with respect to one another to provide for transmission or receiving pair cable length equalization between outer and inner columns of the connector. In other particular embodiments, the cable interconnect interface includes ground referencing to provide for crosstalk control. In still other particular embodiments, the cable interconnect interface includes a signal and ground pad arrangement to provide signal routing in the package substrate for impedance control and avoidance of stub effect. In still other embodiments, the package substrate includes voiding in one or more layers of the substrate under the connector pads to provide improved impedance match and reduction of reflection and return loss. In particular embodiments, the dimensions of the signal pads and ground pads are configured to reduce crosstalk and electromagnetic interference (EMI), as well as reduce reflection and return loss.

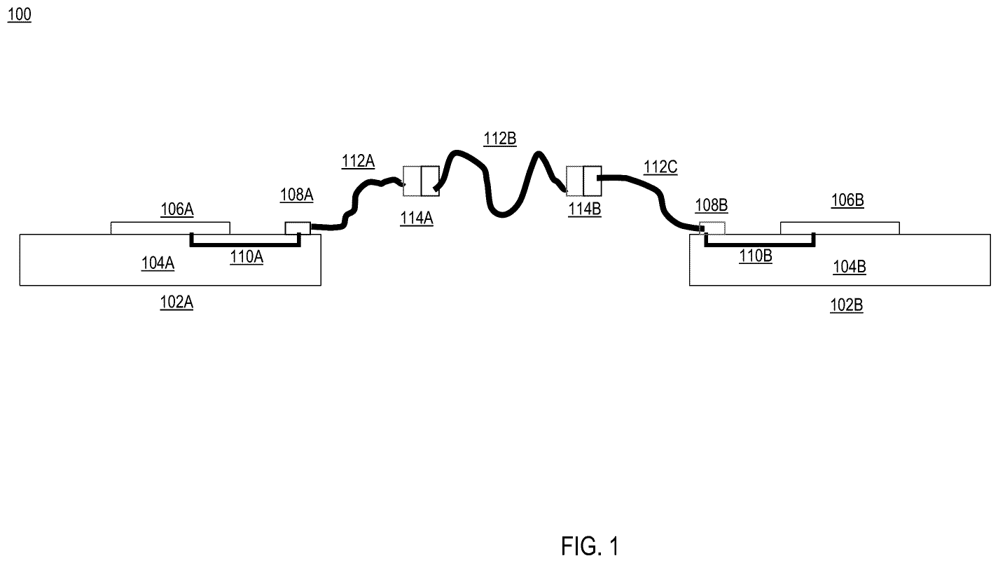

Exemplary methods, apparatus, and products for high-speed connection of package substrates to cable interconnects in accordance with embodiments of the present invention are described with reference to the accompanying drawings, beginning with FIG. 1. FIG. 1 illustrates a system 100 for interconnection of package substrates in accordance with an embodiment. The system 100 includes a first processor package 102A and a second processor package 102B. The first processor package 102A includes a first package substrate 104A and a first processor 106A mounted on the first package substrate 104A. The first processor package 102A further includes a first cable interconnect interface 108A disposed on a top surface of the first package substrate 104A coupled to and in communication with the first processor 106A via first signal traces 110A within one or more layers of the first package substrate 104A. Similarly, the second processor package 102B includes a second package substrate 104B and a second processor 106B mounted on the second package substrate 104B. The second processor package 102B further includes a second cable interconnect interface 108B disposed on a top surface of the second package substrate 104B coupled to and in communication with the second processor 106B via second signal traces 110B within one or more layers of the second package substrate 104B. Although various embodiments are described using a first processor package 102A and a second processor package 102B, it should be understood that in other embodiments any form of semiconductor package may be used.

The system 100 includes a first cable 112A having a first end coupled to the first cable interconnect interface 108A and a second end coupled to a first cable connector 114A. A second cable 112B has a first end coupled to the first cable connector 114A and a second end coupled to a second cable connector 114B. A third cable 112C has a first end coupled to the second cable connector 114B and a second end coupled to the second cable interconnect interface 108B. Accordingly, a high-speed connection between the first processor 106A and the second processor 106B is provided via the coupling of the first cable interconnect interface 108A and the second cable interconnect interface 108B via the cables 112A-112C. In a particular embodiment, the first cable 112A and the third cable 112C are internal to the first processor package 102A and the second processor package 102B, respectively, and the second cable 112B is external to both the first processor package 102A and the second processor package 102B. In various embodiments, the first package substrate 104A, the first cable interconnect interface 108A, the first signal traces 110A, the second package substrate 104B, the second cable interconnect interface 108B, and the second signal traces 110B are configured to provide for improved signal transmission characteristics as further described herein.

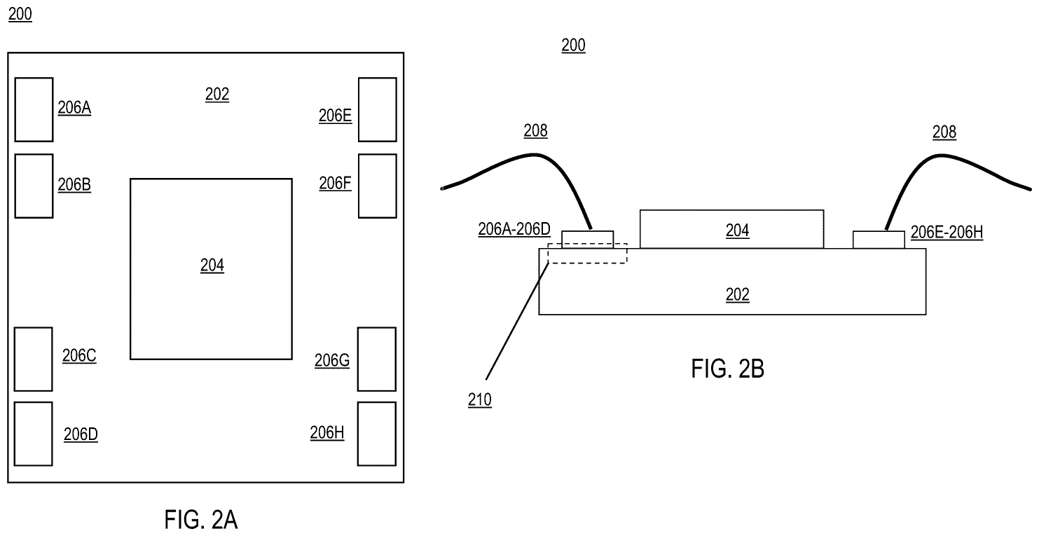

FIGS. 2A-2B illustrate a high-speed connector interface for a processor package 200 in accordance with an embodiment. FIG. 2A illustrates a top view of the processor package 200 and FIG. 2B illustrates a profile view of the processor package 200. The processor package 200 includes a package substrate 202 having an integrated circuit 204, such as a processor, disposed thereon. The package substrate 202 further includes four cable connectors 206A, 206B, 206C, 206D disposed in a first column along a first side of a top surface of the package substrate 202, and four cable connectors 206E, 206F, 206G, 206H disposed in a second column along a second side of the top surface of the package substrate 202. The cable connectors 206A-206H are configured to couple the integrated circuit 204 to other circuitry, such as another integrated circuit, via cables 208. The processor package 200 further includes a cable interconnect interface 210 corresponding to each of the cable connectors 206A-206H formed by the interface of the package substrate 202 and each of the cable connectors 206A-206H as further described below.

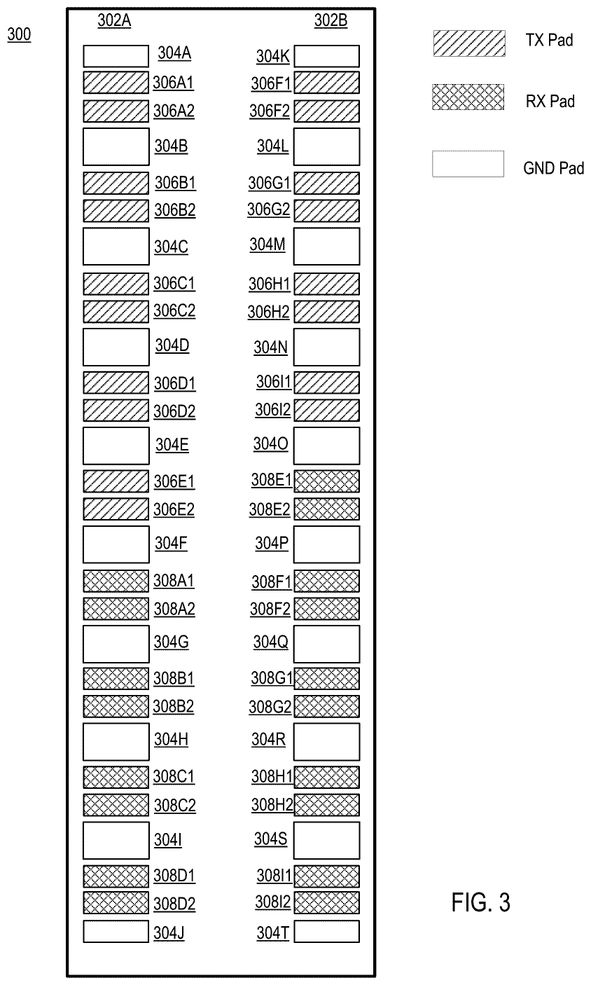

FIG. 3 illustrates a cable connector 300 of a cable interconnect interface in accordance with an embodiment. In one or more embodiments, the cable connector 300 comprises one or more of the connectors 206A-206H described with respect to FIGS. 2A-2B. The cable connector 300 includes a first column 302A of connector pads and a second column 302B of connector pads disposed along opposite sides of the cable connector 300. In a particular embodiment, the first column 302A is an outer column disposed along an outer edge of the cable connector 300 and the second column 302B is an inner column along an inner edge the cable connector 300 with respect to the location of the integrated circuit 204. In the embodiment illustrated in FIG. 3, the first column 302A and the second column 302B collectively include a plurality of ground (GND) connector pads 304A-304T, a plurality of transmission (TX) connector pads 306A1-306I2, and a plurality of receiving (RX) connector pads 308A1-308I2. In particular, the first column 302A includes GND connector pads 304A-304J, TX connector pads 306A1-306E2 forming a first group of TX connector pads, and RX connector pads 308A1-308D2 forming a first group of RX connector pads. The second column 302B includes GND connector pads 304K-304T, TX connector pads 306F1-306I2 forming a second group of TX connector pads, and RX connector pads 308E1-308I2 forming a second group of RX connector pads. Each of the GND connector pads 304A-304T are electrically coupled to a ground plane of the package substrate 202, and each of the TX connector pads 306A1-306I2 and RX connector pads 308A1-308I2 are electrically coupled to the integrated circuit 204 via signal traces within one or more layers of the package substrate 202 such as first signal traces 110A described in FIG. 1.

The TX connector pads 306A1-306I2 are configured to receive signals transmitted from the integrated circuit 204 and send the signals to a cable couple to the cable connector 300. The RX connector pads 308A1-308I2 are configured to receive signals from the cable coupled to the cable connector 300 and send the signals to the integrated circuit 204. In the embodiment illustrated in FIG. 3, the TX connector pads 306A1-306D2 of the first group of TX connector pads are opposite TX connector pads 306F1-306I2 of the second group of TX connector pads, and RX connector pads 308A1-308D2 of the first group of RX connector pads are opposite the RX connector pads second group of receiving connector pads.

In the particular embodiment illustrated in FIG. 3, the TX connector pads 306A1-306I2 and RX connector pads 308A1-308I2 are arranged in differential pairs. For example, TX connector pad 306A1 and TX connector pad 306A2 form a first TX differential pair, and TX connector pad 306B1 and TX connector pad 306B2 form a second differential pair. RX connector pad 308A1 and RX connector pad 308A2 form a first RX differential pair, and RX connector pad 308B1 and RX connector pad 308B2 form a second RX differential pair. Each of the differential pairs has a GND connector pad positioned adjacent to each side of the differential pair. For example, the differential pair formed by TX connector pad 306A1 and TX connector pad 306A2 has GND connector pad 304A and GND connector pad 304B on each side of the differential pair. In the illustrate embodiment, some of the individual GND connector pads have a larger surface area than each of the TX connector pads 306A1-306I2 and RX connector pads 308A1-308I2. For example, GND connector pad 304B has a larger surface area than either TX connector pad 306A1 or TX connector pad 306A2. In one or more embodiments, the distribution of the GND connector pads 304A-304T, the TX connector pads 306A1-306I2, and the RX connector pads 308A1-308I2 provide for improved isolation of crosstalk and coupling noise.

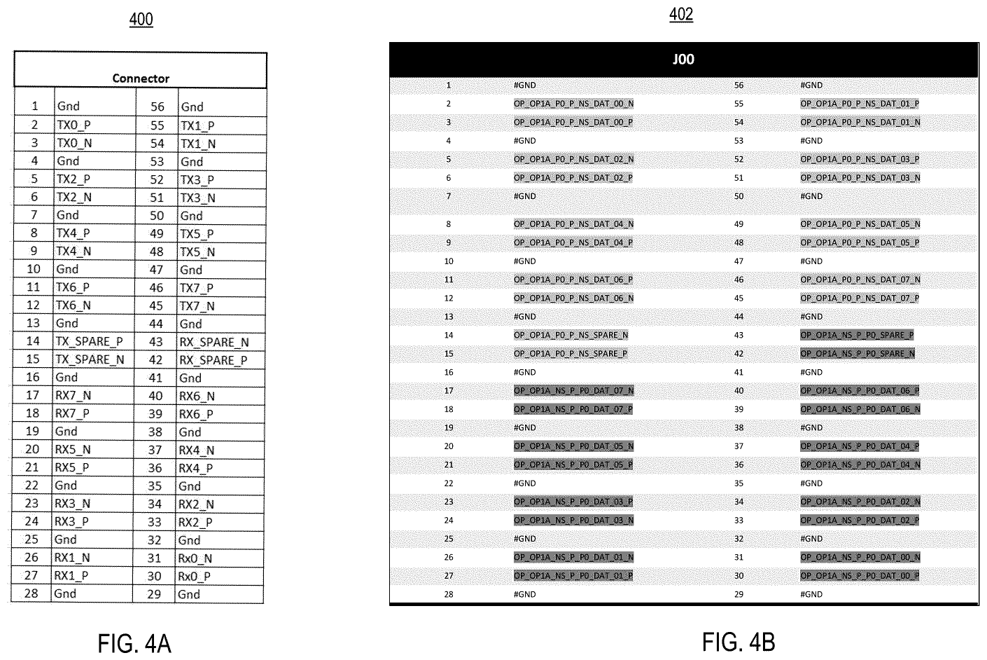

FIGS. 4A-4B illustrate an example TX/RX connector pad placement pattern 400 and signaling designation 402 for the cable connector 300 of FIG. 3 in accordance with an embodiment. The example TX/RX connector pad placement pattern 400 and signaling designation 402 provides for a total of eighteen differential pairs for the cable connector 300 that includes a TX network of nine TX differential pairs and an RX network of nine RX differential pairs.

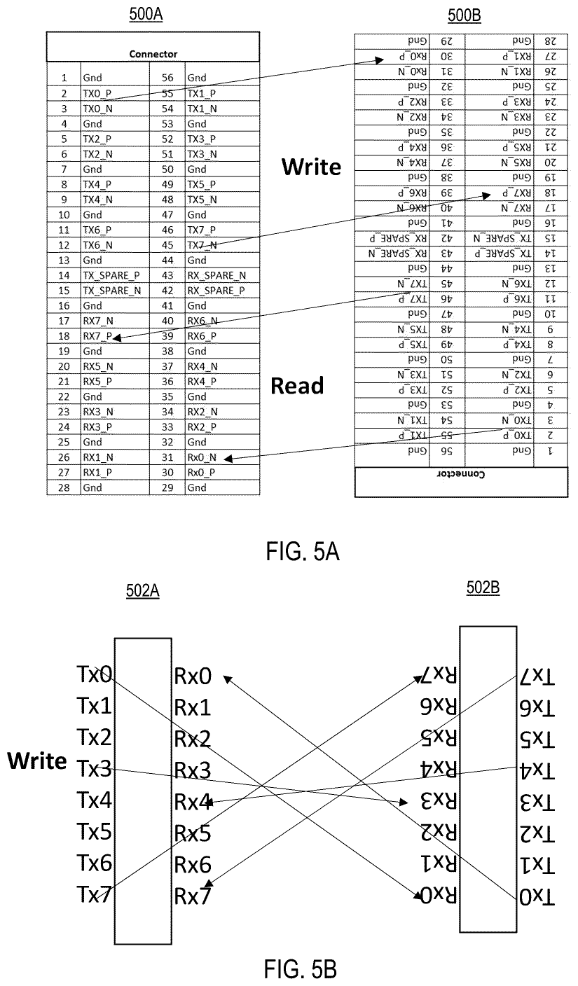

FIG. 5A illustrates an example configuration of cable interconnect interfaces for interconnection of two package substrates in accordance with an embodiment. The configuration includes a first cable connector 500A disposed on a first package substrate such as first package substrate 104A of FIG. 1, and a second cable connector 500B disposed on a second package substrate such as second package substrate 104B of FIG. 1. In a particular embodiment, the first cable connector 500A is arranged according to the TX/RX connector pad placement pattern 400 of FIG. 4A, and the second cable connector 500B is arranged in a connector pad placement pattern that is rotated by one hundred and eighty (180) degrees with respect to the connector pad placement pattern of the first connector. In addition, the connector pad assignments of the first cable connector 500A with respect to the second cable connector 500B are at opposite ends of the respective connectors such that connection of the TX connector pad of one cable connector to the other cable connector may be performed using cables that are of equal length that do not cross over each other.

For example, connector pad 2 (TX0_P) located in the outer column of the first cable connector 500A is connected to connector pad 30 (RX0_P) located in the inner column of the second cable connector 500B such that a write operation may be performed between TX0_P and RX0_P. In another example, connector pad 45 (TX7_N) located in the inner column of the first cable connector 500A is connected to connector pad 18 (RX7_P) located in the outer column of the second cable connector 500B such that a write operation may be performed between TX7_P and RX7_P. In another example, connector pad 2 (TX0_P) located in the outer column of the second cable connector 500B is connected to connector pad 30 (RX0_P) located in the inner column of the first cable connector 500A such that a read operation may be performed between TX0_P and RX0_P. In still another example, connector pad 46 (TX7_P) located in the inner column of the second cable connector 500B is connected to connector pad 18 (RX7_P) located in the outer column of the first cable connector 500A such that a read operation may be performed between TX7_P and RX7_P. Each of the connections between the first cable connector 500A and the second cable connector 500B may be performed using cables of equal length thereby providing TX or RX pair-to-pair cable length equalization.

FIG. 5B illustrates another example configuration of cable interconnect interfaces for interconnection of two package substrates. The configuration includes a first cable connector 502A disposed on a first package substrate such as first package substrate 104A of FIG. 1, and a second cable connector 502B disposed on a second package substrate such as second package substrate 104B of FIG. 1. In a particular embodiment, the first cable connector 502A is arranged according to the TX/RX connector pad placement pattern 400 of FIG. 4A, and the second cable connector 500B is arranged in a connector pad placement pattern that is rotated by one hundred and eighty (180) degrees with respect to the connector pad placement pattern of the first connector. However, the connector pad assignments of the first cable connector 502A with respect to the second cable connector 502B are not rearranged in the manner illustrated in FIG. 5A. Accordingly, the corresponding TX and RX connector pads of the cable connectors are configured such that cable connections between the first cable connector 502A and the second cable connector 502B are connected to opposite ends causing cables to cross over and thus resulting in a cable bundle that is bulky and of unorganized length.

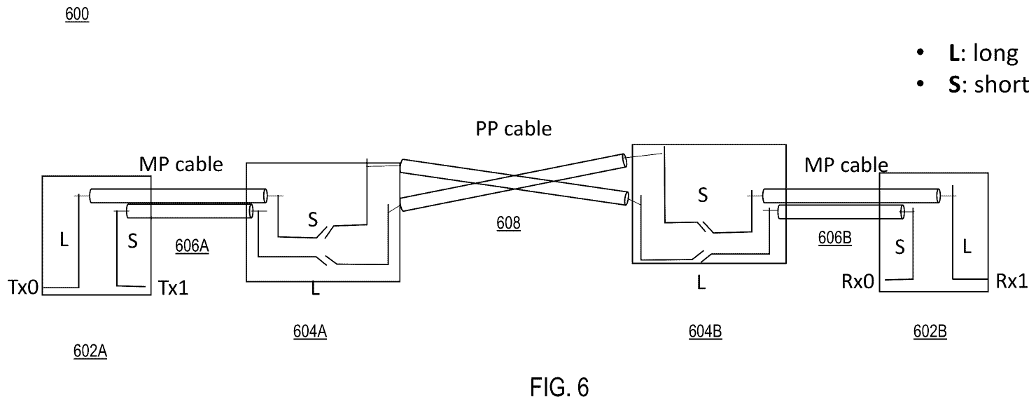

FIG. 6 illustrates an example cable configuration 600 for interconnection of package substrates in accordance with an embodiment. The cable configuration 600 includes a first cable interconnect interface 602A disposed on a top surface of a first package substrate, such as first package substrate 104A coupled to the first processor 106A via first signal traces 110A within one or more layers of the first package substrate 104A. Similarly, a second cable interconnect interface 602B disposed on a top surface of a second package substrate, such as second package substrate 104B coupled to the second processor 106B via second signal traces 110B within one or more layers of the second package substrate 104B. The first cable interconnect interface 602A includes a TX differential pair including a TX connector pad TX0 and a TX connector pad TX1. TX connector pad TX0 is coupled to a first end of a first cable (MP) 606A via a long path (L) and the TX connector pad TX1 is coupled the first end of the first cable 606A via a short path (S). The second end of the first cable 606A is coupled to a first cable connector 604A. In a particular embodiment, the first cable 606A is internal to a first processor package. The first cable connector 604A includes a short path (S) coupled to the long path of the first cable interconnect interface 602A and a long path (L) coupled to the short path of the first cable interconnect interface 602A.

The second cable interconnect interface 602B includes a RX differential pair including a RX connector pad RX0 and a RX connector pad RX1. RX connector pad RX0 is coupled to a first end of a second cable (MP) 606B via a short path (S) and the RX connector pad RX1 is coupled the first end of the second cable 606B via a long path (L). The second end of the second cable 606B is coupled to a second cable connector 604B. In a particular embodiment, the second cable 606B is internal to a second processor package. The second cable connector 604B includes a short path (S) coupled to the long path of the second cable interconnect interface 602B and a long path (L) coupled to the short path of the second cable interconnect interface 602B.

A third cable (PP) 608 having cross conductors is connected between the first cable connector 604A and the second cable connector 604B. In a particular embodiment, the third cable 608 is external to the first processor package and the second processor package. Accordingly, for connector technology with wire terminated on a pin, the pins on one side of the dual inline connector is longer than the other side. Crossing wires in the PP section (i.e., third cable 608) as shown from TX to RX results in a total channel length that is substantially identical for all signals. As a result, length equalization between outer and inner columns the connector is achieved. When the TX side of the channel is swapped in the PP section to the RX side, resonant cancellation due to length equalization is achieved. Without such swapping, reflection in the TX or RX channel creates resonances.

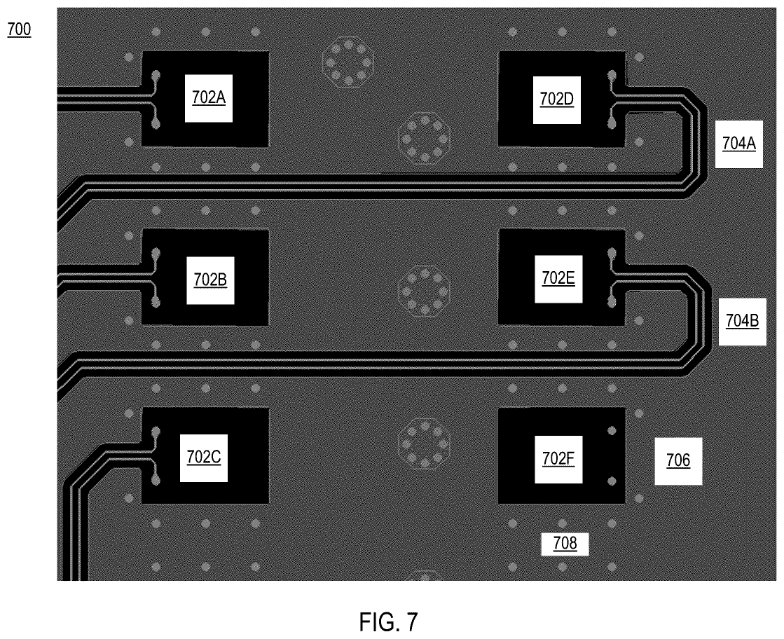

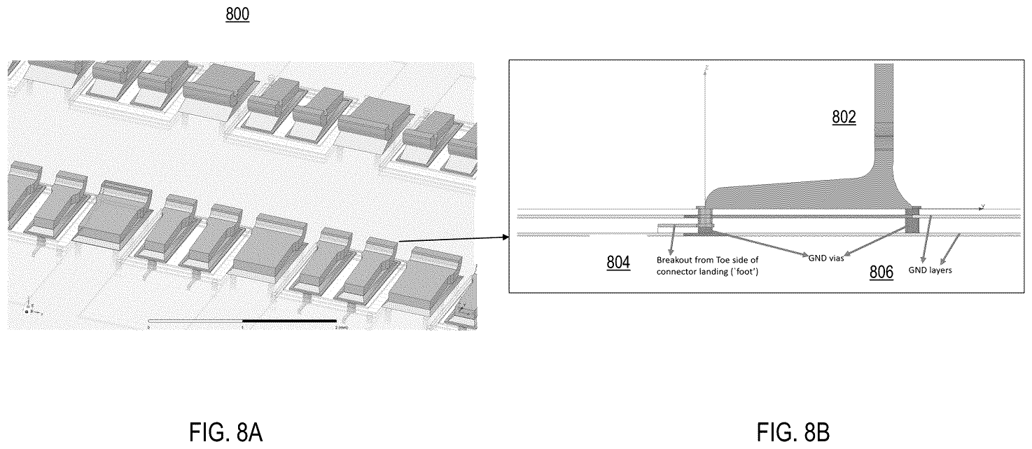

FIG. 7 illustrates a package substrate layer 700 including ground referencing and signal routing at a cable interconnect interface in accordance with an embodiment. The package substrate layer 700 includes a plurality of connector pads 702A, 702B, 702C, 702D, 702E, 702F, a first differential pair signal trace 704A coupled to connector pad 702D, a second differential pair signal trace 704B coupled to connector pad 702E, and a brick-wall ground pattern spaced around three sides of each of the connector pads 702A-702F. The first differential pair signal trace 704A and the second differential pair signal trace 704B enter the connector pads from outside of the connectors to reduce stub effect as further described with respect to FIGS. 8A-8B and/or reduce resonance effect/return loss. The first differential pair signal trace 704A and the second differential pair signal trace 704B further pass between the brick-wall ground patterns 706 surround adjacent connector pads 702A-702F to provide a good ground reference, reduce same layer crosstalk, and to avoid layer-to-layer crosstalk. The brick-wall ground patterns near the connector pads 702A-702F reduce EMI and crosstalk. The package substrate layer 700 may further include ground flooding 708 in the signal layer to reduce EMI and crosstalk.

FIGS. 8A-8B illustrate signal routing in a package at a cable interconnect interface for impedance control to reduce stub effect. FIG. 8A illustrates a perspective view of a plurality connector pads 800 disposed on a substrate. FIG. 8B illustrates an example of stub effect in a connector pad 802. If the connection to the connector pad 802 is located at a toe side 804 of a foot of the connector pad 802, a stub effect may be caused by the signal being required to pass through the foot of the connector pad 802. However, if the connection to the connector pad 802 is located at the heel side 806 of the foot of the connector pad 802, the stub effect is reduced. Accordingly, fanning of the signal from outside of the connector pads reduces or eliminates the stub effect, thus improving the signal quality at the transition.

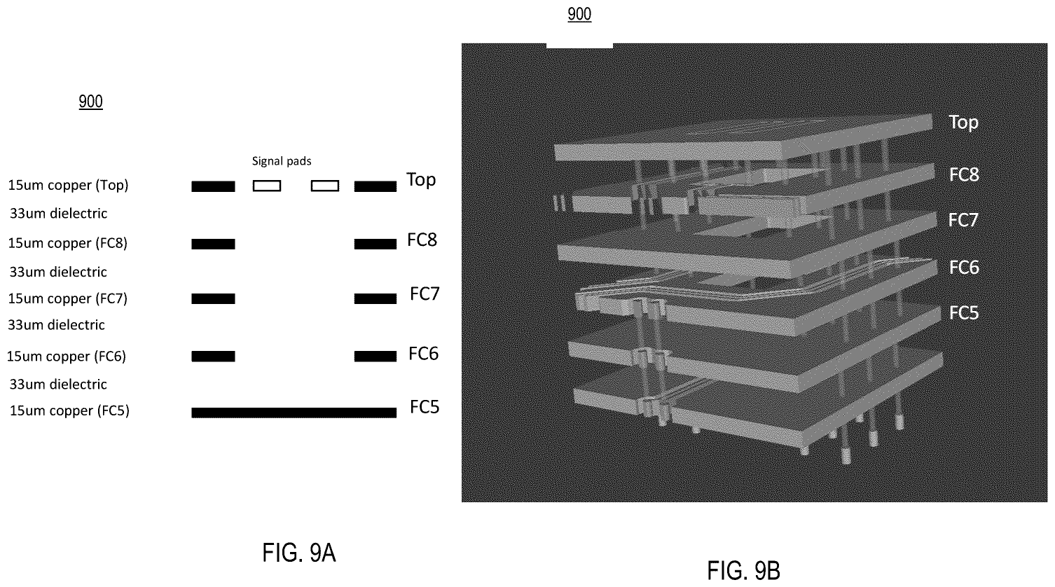

FIGS. 9A-9C illustrate a multilayer package substrate 900 in which one or more layers are voided under the connector pads in accordance with an embodiment. FIG. 9A illustrates a side view of the multilayer package substrate 900 in which a portion of three layers under the signal pads are formed with a void. FIG. 9B illustrates a three-dimensional view of the multilayer package substrate 900. FIG. 9C illustrates a top view of four layers of the multilayer package substrate 900 in which layers FC8, FC7, and FC6 include voids under the signal connectors, and a layer FC5 does not include a void. The dimensions of the voiding and the layers where the voiding is applied of multilayer package substrate 900 are chosen to improve transition impedance match and reduce reflection and/o return loss. In a particular embodiment, the dimensions of the void within the layers is 1260 μm×960 μm. In another particular embodiment, the dimensions of the void within the layers is 1350 μm×1140 μm.

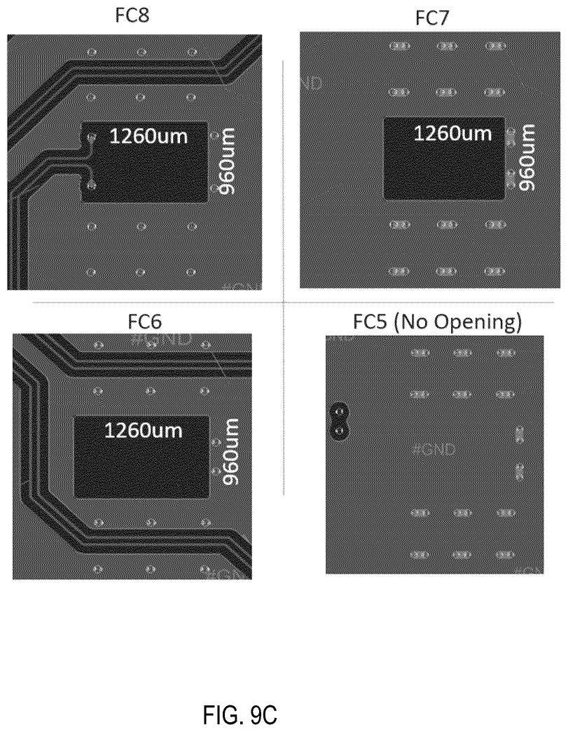

FIG. 10 illustrates a profile view of a connector pad configuration 1000 in accordance with an embodiment. The connector pad configuration 1000 includes a substrate 1002 having a connector pad 1004 disposed thereon. The configuration further includes a solder resist 1006 deposited on the substrate 1002. In particular embodiments, the connector pad 1004 may be cither a signal pad or a ground pad. In particular embodiments, the dimensions of the signal pads and ground pads are chosen to reduce crosstalk and EMI, and reduce reflection and return loss. In a particular embodiment, a solder mask defined (SMD) signal pad is formed having dimensions of 360 μm×1160 μm. In another particular embodiment an SMD ground pad is formed having dimensions of 610 μm×1160 μm. In a particular embodiment, 30 μm for solder resist overlap is assumed.

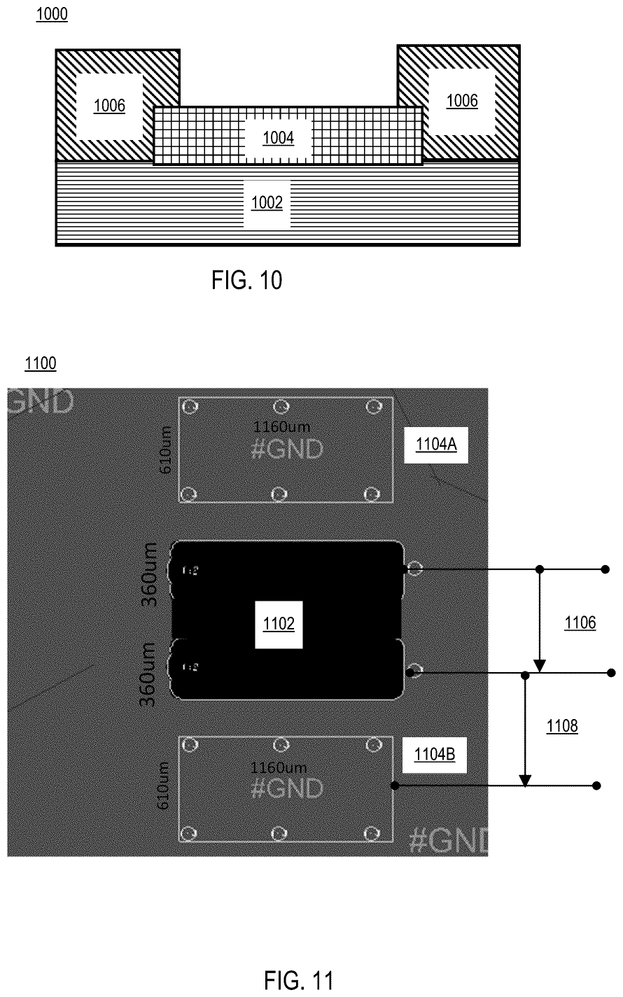

FIG. 11 illustrates a top view of a top layer 1100 of a connector pad configuration in accordance with an embodiment. The top layer includes differential signal pair connector pads 1102, a first ground connector pad 1104A, and a second ground pad connector pad 1104B. In a particular embodiment, a signal pad is formed having dimensions of 360 μm×1160 μm. In another particular embodiment a ground pad is formed having dimensions of 610 μm×1160 μm. In the particular embodiment of FIG. 11, a signal pad to signal pad pitch 1106 is equal to 500 μm, and a ground pad to signal pad pitch 1108 is equal to 625 μm. The dimensions of the signal pads and ground pads are chosen to reduce cross talk and EMI, and reduce reflection and return loss.

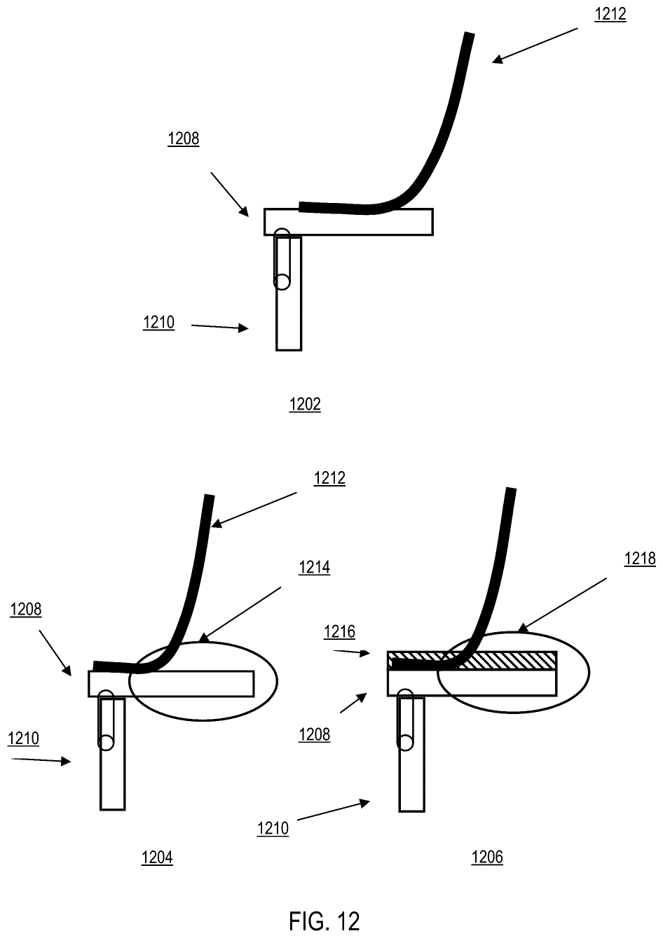

FIG. 12 illustrates another example signal routing in a package at a cable interconnect interface to reduce stub effect in accordance with an embodiment. In a first arrangement 1202 of a cable interconnect interface, a connector pad 1208 is coupled to a via 1210. A cable connector 1212 includes a foot portion that is coupled to and disposed on a surface of the connector pad 1208 in a nominal configuration in which the cable connector 1212 is located in a center position of the connector pad 1208 to minimize stub effect. During manufacture, the foot portion of the cable connector 1212 may land in a non-ideal area of the connector pad 1208. A second arrangement 1204 of a cable interconnector interface illustrates a non-ideal location of the foot portion of the cable connector 1212 on the connector pad 1208 such that a significant stub effect 1214 is created.

A third arrangement 1206 of the cable interconnect interface includes the foot portion of the cable connector 1212 positioned in the connect pad 1208 in the same manner as the second arrangement 1204. However, the third arrangement 1206 further includes a radio frequency absorption layer 1216 disposed on the surface of the connector pad 1208. The foot portion of the cable connector 1212 is disposed within the radio frequency absorption layer 1216. The radio frequency absorption layer 1216 is comprised of a radio frequency adsorption material or other lossy material such as a cavity resonance absorption paste material, a flexible dielectric foam absorber, a carbon-foam, or any equivalent material. In particular embodiments, the radio frequency absorption layer 1216 is applied to the connector pad 1208 via spraying or coating. The radio frequency absorption layer 1216 suppresses or mitigates higher frequency resonance due to stubbing thereby providing a reduced stub effect 1218. Accordingly, the stub effect due to non-ideal placement of the cable connector 1212 on the connector pad 1208 is greatly reduced or eliminated, thus improving the signal quality of the connection. In one or more embodiments, the radio frequency absorption layer 1216 may be applied to any of the cable interconnect interface described herein to mitigate stub effect.

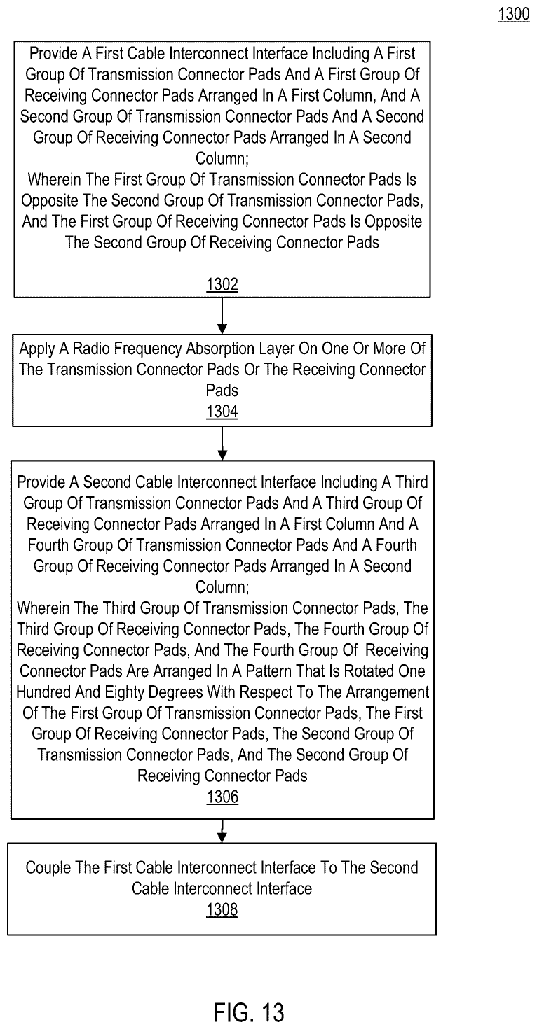

For further explanation, FIG. 13 sets forth a flow chart illustrating an exemplary method 1300 for high-speed connection to a cable interconnect according to embodiments of the present invention. The method 1300 includes providing 1302 a first cable interconnect interface disposed on a first substrate, the first cable interconnect interface including a first group of transmission connector pads and a first group of receiving connector pads arranged in a first column of the first cable interconnect interface, and a second group of transmission connector pads and a second group of receiving connector pads arranged in a second column of the first cable interconnect interface. The first group of transmission connector pads is opposite the second group of transmission connector pads, and the first group of receiving connector pads is opposite the second group of receiving connector pads.

The method further includes applying 1304 a radio frequency absorption layer on one or more of the transmission connector pads and the receiving connector pads. The method 1300 further includes providing 1306 a second cable interconnect interface disposed on a second substrate, the second cable interconnect connector including a third group of transmission connector pads and a third group of receiving connector pads arranged in a first column of the second cable interconnect interface, and a fourth group of transmission connector pads and a fourth group of receiving connector pads arranged in a second column of the second cable interconnect interface. The third group of transmission connector pads, the third group of receiving connector pads, the fourth group of receiving connector pads, and the fourth group of receiving connector pads are arranged on the second cable interconnect interface in a pattern that is rotated one hundred and eighty degrees with respect to the arrangement of the first group of transmission connector pads, the first group of receiving connector pads, the second group of transmission connector pads, and the second group of receiving connector pads.

The method 1300 further includes coupling 1308 the first cable interconnect interface to the second cable interconnect interface.

In view of the explanations set forth above, readers will recognize that the benefits of high-speed connection of package substrates to cable interconnects according to embodiments of the present invention include:
TX/RX and ground distribution for improved isolation of crosstalk and reduced coupling noise.
Improved ground referencing in the package at the cable interconnect interface for crosstalk control
Improved signal routing in the package at the cable interconnect interface for impedance control and stub effect avoidance.
Reduced crosstalk, EMI, reflection, and return loss at the cable interconnect interface.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A semiconductor package for high-speed connection to a cable interconnect, comprising:
an integrated circuit disposed on a substrate; and
a cable interconnect interface disposed on the substrate and in communication with the integrated circuit, the cable interconnect interface including a first plurality of connector pads arranged in a first column of the cable interconnect interface and a second plurality of connector pads arranged in a second column of the cable interconnect interface;
a radio frequency absorption layer disposed on one or more of the first plurality of connector pads and the second plurality of connector pads;
wherein the first plurality of connector pads includes a first group of transmission connector pads and a first group of receiving connector pads, and the second plurality of connector pads includes a second group of transmission connector pads and a second group of receiving connector pads; and
wherein the first group of transmission connector pads is opposite the second group of transmission connector pads, and the first group of receiving connector pads is opposite the second group of receiving connector pads.

2. The semiconductor package of claim 1, wherein the first plurality of connector pads are configured as differential pairs.

3. The semiconductor package of claim 2, wherein the cable interconnect interface further includes one or more ground pads adjacent to one or more of the differential pairs.

4. The semiconductor package of claim 3, wherein a surface area of the one or more ground pads is larger than a surface area of one of the first plurality of connector pads.

5. The semiconductor package of claim 1, wherein the substrate comprises a first layer including a signal trace coupled to a first connector pad of the plurality of connector pads, wherein the signal trace being coupled to the first connector pad at an outer portion of the first connector pad.

6. The semiconductor package of claim 5, wherein the substrate further includes a ground pattern spaced around one or more sides of the first connector pad.

7. The semiconductor package of claim 6, wherein the signal traces passes through a portion of the ground pattern.

8. The semiconductor package of claim 5, wherein the substrate further comprises a second layer, wherein the second layer includes a void formed therein.

9. The semiconductor package of claim 8, wherein the void is located under at least a portion of the first connector pad.

10. The semiconductor package of claim 1, wherein the first column is positioned along a first side of the cable interconnect interface, and the second column is positioned along a second side of the cable interconnect interface.

11. The semiconductor package of claim 10, wherein the first side is positioned opposite of the first side.

12. The semiconductor package of claim 1, further comprising a cable connector having a foot portion coupled to the one or more of the first plurality of connector pads and the second plurality of connector pads, wherein the foot portion is disposed within the radio frequency absorption layer.

13. A system for high-speed connection to a cable interconnect, comprising:
a first semiconductor package comprising:
a first cable interconnect interface disposed on a first substrate, the first cable interconnect interface including a first group of transmission connector pads and a first group of receiving connector pads arranged in a first column of the first cable interconnect interface, and a second group of transmission connector pads and a second group of receiving connector pads arranged in a second column of the first cable interconnect interface;
a radio frequency absorption layer disposed on one or more of the transmission connector pads or the receiving connector pads; and
wherein the first group of transmission connector pads is opposite the second group of transmission connector pads, and the first group of receiving connector pads is opposite the second group of receiving connector pads.

14. The system of claim 13, further comprising:
a second semiconductor package comprising:
a second cable interconnect interface disposed on a second substrate, the second cable interconnect interface including a third group of transmission connector pads and a third group of receiving connector pads arranged in a first column of the second cable interconnect interface, and a fourth group of transmission connector pads and a fourth group of receiving connector pads arranged in a second column of the second cable interconnect interface; and
wherein the third group of transmission connector pads, the third group of receiving connector pads, the fourth group of receiving connector pads, and the fourth group of receiving connector pads are arranged on the second cable interconnect interface in a pattern that is rotated one hundred and eighty degrees with respect to the arrangement of the first group of transmission connector pads, the first group of receiving connector pads, the second group of transmission connector pads, and the second group of receiving connector pads.

15. The system of claim 14, further comprising:
a first integrated circuit disposed on the first substrate and in communication with the first cable interconnect interface; and
a second integrated circuit disposed on the second substrate and in communication with the second cable interconnect interface.

16. The system of claim 14, further comprising:
a cable configured to couple the first cable interconnect interface to the second cable interconnect interface.

17. The system of claim 16, wherein the cable is configured to couple one of the first group of transmission connector pads of the first cable interconnect interface to one of the third group of receiving connector pads of the second cable interconnect interface.

18. The system of claim 16, wherein the cable is configured to couple one of the third group of transmission connector pads of the second cable interconnect interface to one of the first group of receiving connector pads of the first cable interconnect interface.

19. A method for high-speed connection to a cable interconnect, comprising:
providing a first cable interconnect interface disposed on a first substrate, the first cable interconnect interface including a first group of transmission connector pads and a first group of receiving connector pads arranged in a first column of the first cable interconnect interface, and a second group of transmission connector pads and a second group of receiving connector pads arranged in a second column of the first cable interconnect interface; and
applying a radio frequency absorption layer on one or more of the transmission connector pads and the receiving connector pads;
wherein the first group of transmission connector pads is opposite the second group of transmission connector pads, and the first group of receiving connector pads is opposite the second group of receiving connector pads.

20. The method of claim 19, further comprising:
providing a second cable interconnect interface disposed on a second substrate, the second cable interconnect connector including a third group of transmission connector pads and a third group of receiving connector pads arranged in a first column of the second cable interconnect interface, and a fourth group of transmission connector pads and a fourth group of receiving connector pads arranged in a second column of the second cable interconnect interface;
wherein the third group of transmission connector pads, the third group of receiving connector pads, the fourth group of receiving connector pads, and the fourth group of receiving connector pads are arranged on the second cable interconnect interface in a pattern that is rotated one hundred and eighty degrees with respect to the arrangement of the first group of transmission connector pads, the first group of receiving connector pads, the second group of transmission connector pads, and the second group of receiving connector pads; and coupling the first cable interconnect interface to the second cable interconnect interface.
